(19) United States
(12) Patent Application Publication
(10) Pub. No.: US 2016/0260691 A1
(43) Pub. Date: Sep. 8, 2016

(54) SEMICONDUCTOR MODULE

(71) Applicant: TOYOTA JIDOSHA KABUSHIKI KAISHA, Toyota-shi, Aichi-ken (JP)

(72) Inventor: Masaki AOSHIMA, Toyota-shi (JP)

(73) Assignee: TOYOTA JIDOSHA KABUSHIKI KAISHA, Toyota-shi, Aichi-ken (JP)

(21) Appl. No.: 14/912,547

(22) PCT Filed: Aug. 27, 2014
(86) PCT No.: PCT/JP2014/072455

§ 371 Date: Feb. 17, 2016

(30) Foreign Application Priority Data
Oct. 7, 2013 (JP) 2013-210188

(51) Int. Cl. H01L 25/065; H01L 23/498; H01L 23/00; H01L 27/082

(52) U.S. Cl. CPC H01L 25/0657; H01L 27/0823; H01L 23/49805; H01L 24/49; H01L 24/73; H01L 24/10; H01L 24/32; H01L 2225/06575; H01L 2225/06548; H01L 2225/0651; H01L 2224/49176; H01L 2224/49431; H01L 2224/49433; H01L 2924/13055; H01L 2924/19107; H01L 2224/32225

(57) ABSTRACT

A semiconductor module includes: a first semiconductor chip including a surface provided with a first signal electrode; a second semiconductor chip arranged apart from the first semiconductor chip and including a surface on the first semiconductor chip side provided with a second signal electrode; a first signal lead electrically connected to the first signal electrode; and a second signal lead electrically connected to the second signal electrode. The first signal lead and the second signal lead are arranged so that a height position of the first signal lead and a height position of the second signal lead match in a height direction that is toward the second semiconductor chip from the first semiconductor chip.

### TECHNICAL FIELD

The present invention relates to a semiconductor module.

### BACKGROUND ART

Patent Literature 1 (Japanese Patent Application Publication No. 2009-295794) discloses a semiconductor device provided with a pair of semiconductor chips arranged adjacent one another in an up and down direction. The pair of semiconductor chips is arranged so that their emitter electrodes face each other. Each semiconductor chip is connected via a wire to a control terminal. The control terminals are respectively arranged adjacent one another with an interval in between in the up and down direction.

### SUMMARY OF INVENTION

### Technical Problem

In the technique disclosed in Patent Literature 1, the control terminals for each of the semiconductor chips are arranged adjacent one another with an interval in between in the up and down direction, as a result of which a height of an entirety of the semiconductor device in the up and down direction becomes high, and there had been a problem that the device had to have a large size. Thus, the present disclosure aims to provide a semiconductor module of which size can be reduced.

### Solution to Technical Problem

A semiconductor module disclosed herein may include: a first semiconductor chip including a surface provided with a first signal electrode, and a second semiconductor chip arranged apart from the first semiconductor chip and including a surface on the first semiconductor chip side provided with a second signal electrode. Further, the semiconductor module may include a first signal lead electrically connected to the first signal electrode, and a second signal lead electrically connected to the second signal electrode. The first signal lead and the second signal lead may be arranged so that a height position of the first signal lead and a height position of the second signal lead match in a height direction that is toward the second semiconductor chip from the first semiconductor chip.

According to such a configuration, since the first signal lead and the second signal lead are arranged to have their height positions match in the height direction from the first semiconductor chip toward the second semiconductor chip, so a width of the semiconductor module in this direction can be made small.

The semiconductor module described above may further include an insulator arranged between the first semiconductor chip and the second semiconductor chip, a first signal pattern provided on a surface of the insulator on the first semiconductor chip side, and a second signal pattern provided on a surface of the insulator on a second semiconductor chip side. The first signal electrode may be electrically connected to the first signal lead through the first signal pattern, and the second signal electrode may be electrically connected to the second signal lead through the second signal pattern.

### BRIEF DESCRIPTION OF DRAWINGS

FIG. 1 is a vertical cross sectional view of a semiconductor module of an embodiment.

FIG. 2 is a II-II cross sectional view of FIG. 1.

FIG. 3 is a perspective view showing an enlarged view of a part of constituent features of She semiconductor module.

FIG. 4 is a perspective view showing an enlarged view of a part of constituent features of the semiconductor module.

FIG. 5 is a cross sectional view of a semiconductor module of another embodiment, corresponding to FIG. 2.

FIG. 6 is a vertical cross sectional view of a semiconductor module of yet another embodiment.

FIG. 7 is a VII-VII cross sectional view of FIG. 6.

FIG. 8 is a perspective view showing an enlarged view of a part of constituent features of the semiconductor module.

FIG. 9 is a vertical cross sectional view of a semiconductor module of yet another embodiment.

FIG. 10 is a cross sectional view of a semiconductor module of yet another embodiment, corresponding to FIG. 2.

### DESCRIPTION OF EMBODIMENTS

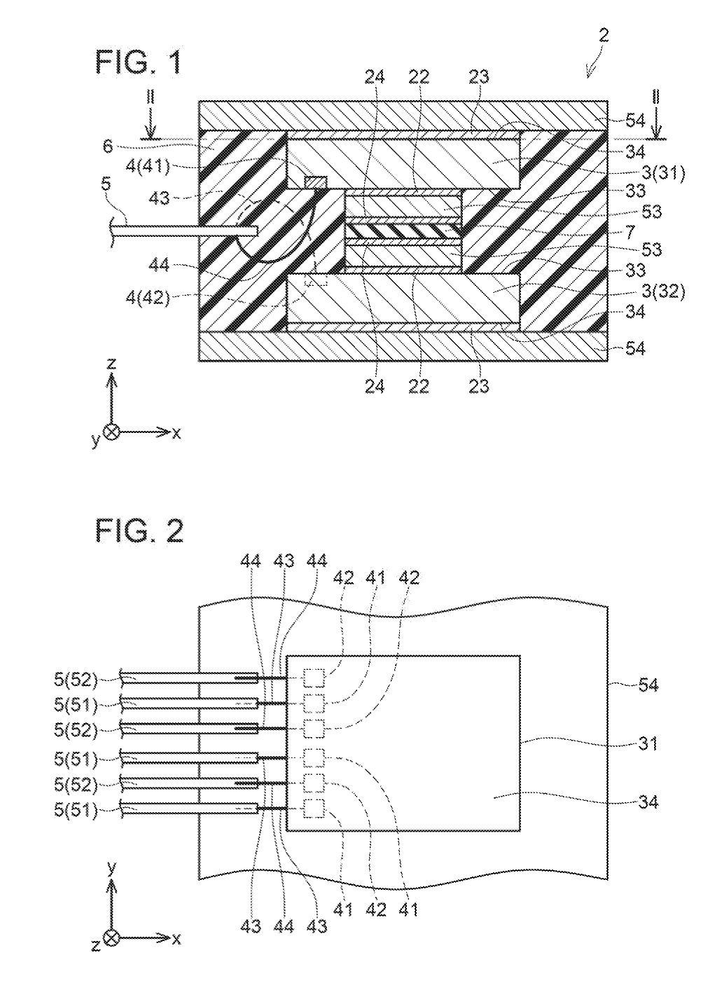

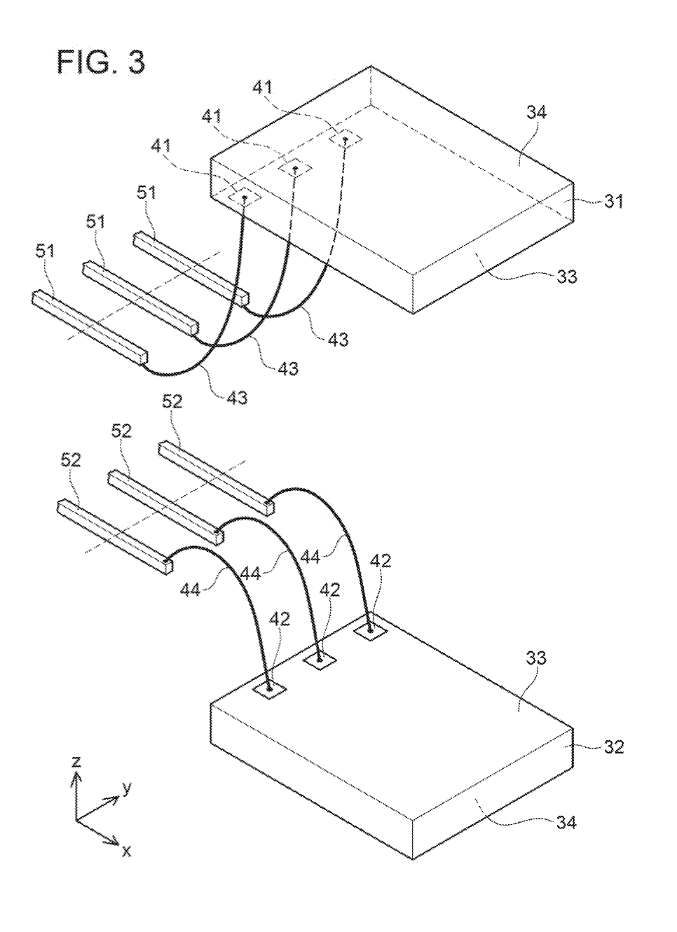

Hereinbelow, embodiments will be described with reference to the attached drawings. As shown in FIG. 1 to FIG. 3, a semiconductor module 2 of an embodiment comprises a pair of semiconductor chips 3 (first semiconductor chip 31 and second semiconductor chip 32), and a plurality of signal leads 5 (first signal leads 51 and second signal leads 52). Notably in FIG. 3, the first semiconductor chip 31 and the second semiconductor chip 32 as well as the first signal leads 51 and the second signal leads 52 are shown in a state of being separated in an up and down direction (z direction) for easier view. Further, the semiconductor module 2 comprises emitter leads 53 and collector leads 54 corresponding respectively to the semiconductor chips 3. Further, the semiconductor module 2 comprises sealing resin 6 that seals an entirety thereof.

In the embodiment, IGBTs (Insulated Gate Bipolar Transistors) are used as the semiconductor chips 3. The first semiconductor chip 31 and the second semiconductor chip 32 are arranged with an interval therebetween in the up and down direction (z direction). In the example shown in FIG. 1, the first semiconductor chip 31 is arranged above the second semiconductor chip 32. Each of the pair of semiconductor chips 3 (first semiconductor chip 31 and second semiconductor chip 32) comprises a front surface 33 and a rear surface 34, and they are arranged so that their front surfaces 33 face each other. That is, the front surface 33 of the first semiconductor chip 31 faces downward, and the front surface 33 of the second semiconductor chip 32 feces upward (the rear surface 34 of the first semiconductor chip 31 faces upward, and the rear surface 34 of the second semiconductor chip 32 faces downward). An emitter electrode (omitted from drawings) is provided on the front surface 33 and a collector electrode (omitted from drawings) is provided on the rear surface 34 of each semiconductor chip 3. An emitter lead 53 is arranged at a position adjacent to each emitter electrode. Each emitter electrode is connected to its adjacent emitter lead 53 by a solder 22. A collector lead 54 is arranged at a position adjacent to each collector electrode. Each collector electrode is connected to its adjacent collector lead 54 by a solder 23. That is, each semiconductor chip 3 is arranged between its emitter lead 53 and collector lead 54. The collector leads 54 function as heat sinks. Heat generated respectively in the semiconductor chips 3 (first semiconductor chip 31 and second semiconductor chip 32) is discharged outside via the collector leads 54 (heat sinks).

A plate-shaped insulator 7 is arranged between the upper and lower emitter leads 53. Metal layers are provided respectively on front and rear surfaces of the insulator 7. The metal layers on the front and rear surfaces of the insulator 7 are fixed to corresponding emitter leads 53 via solders 24. The upper and lower emitter leads 53 are insulated by the insulator 7.

A cooler (omitted from drawings) for cooling the semiconductor chips 3 is arranged on outside of each of the collector leads 54. Further, the sealing resin 6 for sealing the semiconductor chip 3 is filled between the upper and lower collector leads 54.

The upper first semiconductor chip 31 comprises a plurality of first signal electrodes 41 provided on its front surface 33, and the lower second semiconductor chip 32 comprises a plurality of second signal electrodes 42 provided on its front surface 33. Each of signal electrodes 4 (first signal electrodes 41 and second signal electrodes 42) is provided adjacent to its corresponding emitter electrode. The signal electrodes 4 are electrodes for sending and receiving control signals between the semiconductor chips 3 and external devices (omitted from drawings). The plurality of signal electrodes 4 is provided adjacent to one another with intervals in between in a plan view, as shown in FIG. 2. The first signal electrodes 41 and the second signal electrodes 42 are provided to be laterally offset, so that they do not overlap one another in the plan view. In the present embodiment, the first signal electrodes 41 and the second signal electrodes 42 are arranged so as to be alternate one another in the plan view. Due to this, the first signal electrodes 41 and the second signal electrodes 42 are configured so as not to overlap each other in the up and down direction (z direction).

Each of the signal leads 5 is covered partially by the sealing resin 6, and has a part protruding to the outside of the sealing resin 6. Each of the signal leads 5 (first signal leads 51 and second signal leads 52) is connected to a corresponding signal electrode 4 (first signal electrode 41 or second signal electrode 42) via a metal wire (first wire 43 or second wire 44). The first signal leads 51 are electrically connected to the first signal electrodes 41 via the first wires 43, and the second signal leads 52 are electrically connected to the second signal electrodes 42 via the second wires 44. The signal leads 5 are arranged so as to extend in parallel with intervals in between. The first signal leads and the second signal leads are arranged alternately. Accordingly, the first wires 43 and the second wires 44 are arranged alternately. As shown in FIG. 3, the first wires 43 are curved so as to protrude downward. One ends of the first wires 43 are connected to the first signal electrodes 41 from below the first signal electrodes 41, and the other ends thereof are connected to the first signal leads 51 from below the first signal leads 51. The second wires 44 are curved so as to protrude upward. One ends of the second wires 44 ore connected to the second signal electrodes 42 from above the second signal electrodes 42, and the other ends thereof are connected to the second signal leads 52 from above the second signal leads 52.

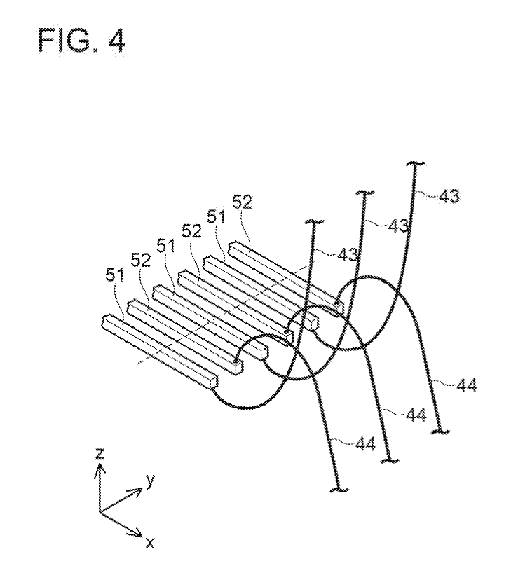

The respective signal leads 5 (first signal leads 51 and second signal leads 52) are arranged in a line along a lateral direction (y direction) as shown in FIG. 4. Further, the respective signal leads 5 (first signal leads 51 and second signal leads 52) extend from the outside of the sealing resin 6 toward a region located between the semiconductor chips 3 (that is, along an x direction) (see FIG. 1). Further, the signal leads 5 (first signal leads 51 and second signal leads 52) are arranged so that their height positions match in a height direction along the up and down direction (z direction), that is, in the height direction from the first semiconductor chip 31 toward the second semiconductor chip 32. In the present description, “the height positions being matched” is not limited strictly to an identical height, but is a concept that includes a state in which heights may somewhat differ. A deviation of the height positions among the plurality of signal leads 5 is preferably within a range of manufacture error from a viewpoint of achieving a size reduction in the semiconductor module. The range of manufacture error is preferably a range of 0 to 100 μm. That is, a difference among the height positions of the signal leads 5 is preferably equal to or less than 100 μm at maximum. Further, the signal leads 5 (first signal leads 51 and second signal leads 52) are preferably configured such that the first signal leads 51 and the second signal leads 52 overlap each other at least partially as seen along a direction along which the signal leads 5 are aligned (y direction). By the signal leads 5 being overlapped when seen along the y direction, the deviation in the height positions of the signal leads 5 in the z direction becomes smaller.

According to the semiconductor module 2 having the above configuration, its width in the up and down direction can be made small by having the height positions of the plurality of signal leads 5 in the up and down direction (z direction) match. Accordingly, the size reduction of the semiconductor module 2 can be achieved.

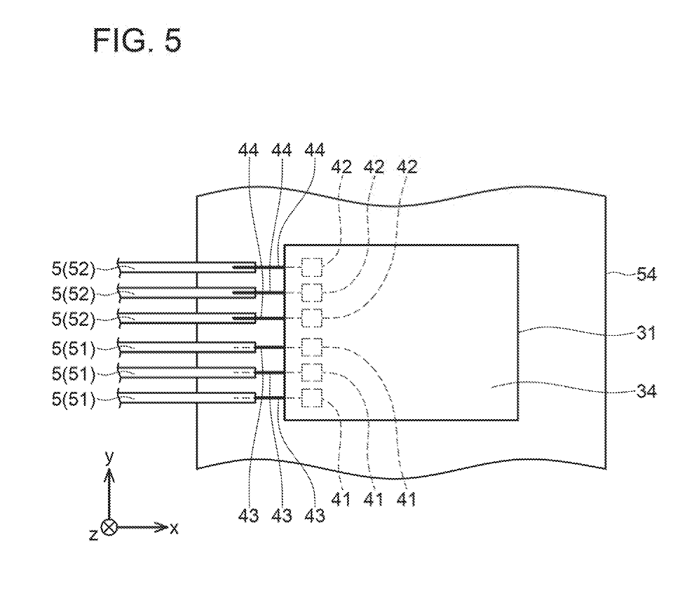

As above, an embodiment has been described, however, the specific configuration is not limited to the above embodiment. For example, the first signal electrodes 41 and the second signal electrodes 42 are aligned alternately in the plan view in the above embodiment, however, no limitation is made to this configuration. As shown in FIG. 5, the configuration may have the plurality of first signal electrodes 41 arranged by being gathered on one side and the second signal electrodes 42 arranged by being gathered on the other side in the plan view. Notably the configurations in FIG. 5 that are identical to FIG. 2 will be given the same reference signs, and the description thereof will be omitted. According to such a configuration as well, the first signal electrodes 41 and the second signal electrodes 42 are not overlapped in the up and down direction (z direction). The first wires 43 and the second wires 44 can be prevented from making contact with each other by offsetting the positions of the first signal electrodes 41 and the second signal electrodes 42.

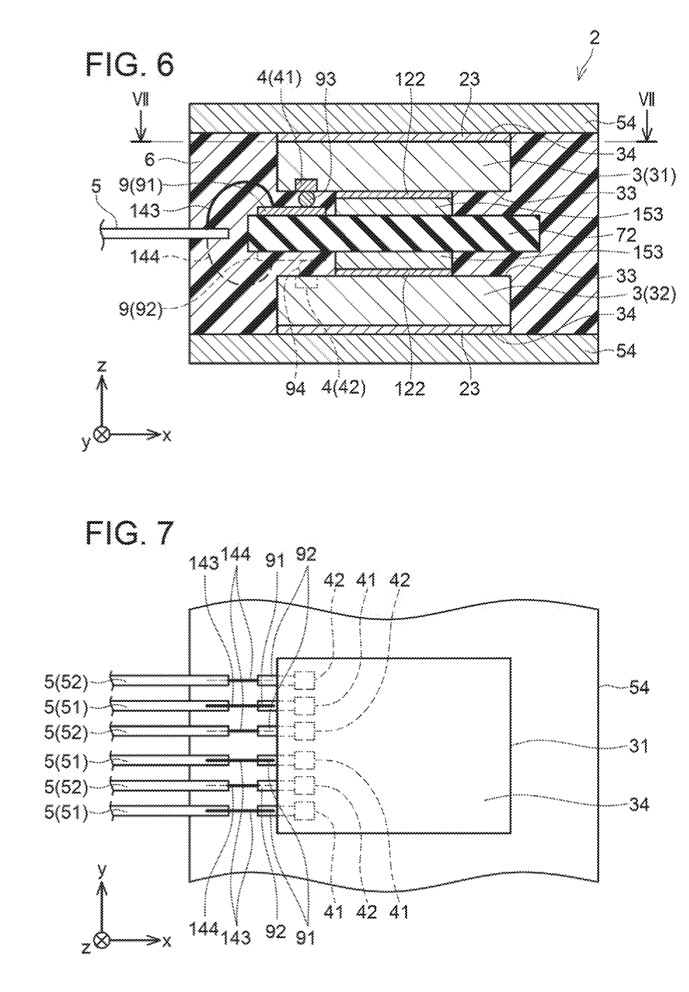

Further, the configuration that electrically connects the signal electrodes 4 and the signal leads 5 is not limited to the above embodiment. For example, as shown in FIG. 6 and FIG. 7, the signal electrodes 4 and the signal leads 5 may be electrically connected via signal patterns 9. The configurations in FIG. 6 and FIG. 7 that are identical to FIG. 1 and FIG. 2 will be given the same reference signs, and the description thereof will be omitted. In the embodiment shown in FIG. 6 and FIG. 7, the semiconductor module 2 comprises the insulator 72 arranged between the pair of semiconductor chips 3, and the signal patterns 9 (first signal patterns 91 and second signal patterns 92) respectively arranged on the surfaces of the insulator 72. The insulator 72 is configured of insulating ceramics. The insulator 72 is arranged between the first semiconductor chip 31 and the second semiconductor chip 32. The first signal patterns 91 are provided on the front surface (upper surface) of the insulator 72, and the second signal patterns 92 are provided on the rear surface (lower surface) of the insulator 72. That is, the first signal patterns 91 are provided on the surface of the insulator 72 on a first semiconductor chip 31 side, and the second signal patterns 92 are provided on the surface of the insulator 72 on a second semiconductor chip 32 side. Further, emitter patterns 153 are provided on the front and rear surfaces of the insulator 72. The signal patterns 9 and the emitter patterns 153 are configured of metal such as aluminum or copper. The signal patterns 9 and the emitter patterns 153 are separated from each other.

The signal patterns 9 are electrically connected to the signal electrodes 4 (first signal electrodes 41 or second signal electrodes 42) via metal solder (first solders 93 or second solders 94). The first signal patients 91 are fixed to the first signal electrodes 41 by the first solders 93. The second signal patterns 92 are fixed to the second signal electrodes 42 by the second solders 94.

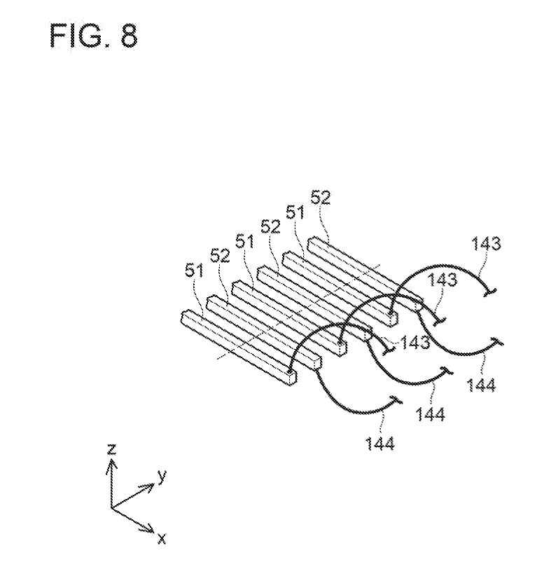

The signal leads 5 (first signal leads 51 or second signal leads 52) are connected to the signal patterns 9 (first signal patterns 91 or the second signal patterns 92) by metal wires (first wires 143 or second wires 144). One ends of the first wires 143 are connected to the first signal patterns 91 from above the first signal patterns 91, and the other ends thereof are connected to the first signal leads 51 from above the first signal leads 51 as shown in FIG. 8. One ends of the second wires 144 are connected to the second signal patterns 92 from below the second signal patterns 92, and the other ends thereof are connected to the second signal leads 52 from below the second signal leads 52. The first wires 143 extend upward from the first signal patterns 91 and the first signal leads 51. The second wires 144 extend downward from the second signal patterns 92 and the second signal leads 52. The first signal leads 51 are electrically connected to the first signal electrodes 41 via the first wires 143, the first signal patterns 91, and the first solders 93. The second signal leads 52 are electrically connected to the second signal electrodes 42 via the second wires 144, the second signal patterns 92, and the second solders 94.

The emitter patterns 153 are respectively fixed to the front surfaces 33 of the semiconductor chips 3 by solders 122. Due to this, the emitter electrodes on the front surface sides of the semiconductor chips 3 are electrically connected to the emitter patterns 153.

According to such a configuration, contacts between the wires (first wires 143 and second wires 144) can be prevented by electrically connecting the signal electrodes 4 and the signal leads 5 via the signal patterns 9 as shown in FIG. 8. That is, without the intervention of the signal patterns 9, there is a possibility that the wires 143 and 144 make contact by the first wires 143 and the second wires 144 intersecting one another. However, with the intervention of the signal patterns 9, the contact between the wires 143 and 144 can be prevented, since the first wires 143 and the second wires 144 do not intersect one another.

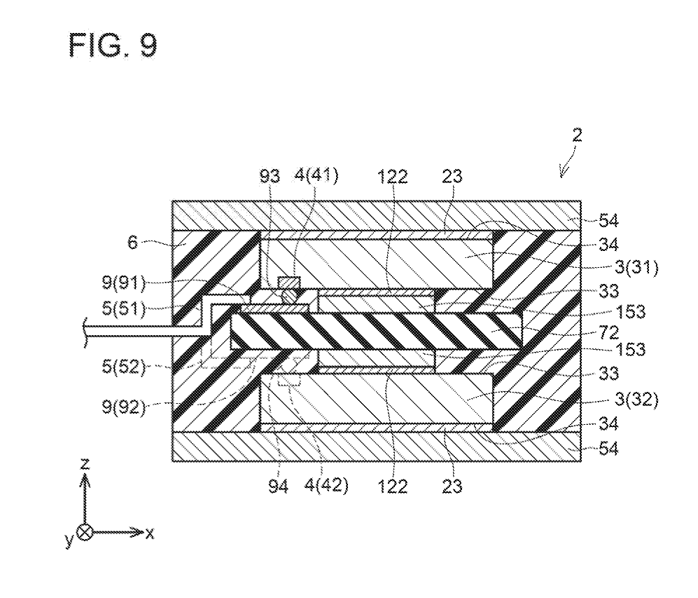

Further, in the above embodiment, the wires are used to electrically connect the signal electrodes 4 and the signal leads 5, however, wires may not necessarily be used. For example, as shown in FIG. 9, the signal leads 5 (first signal leads 51 and second signal leads 52) may be configured to be directly connected to the signal patterns 9 (first signal patterns 91 and second signal patterns 92). In FIG. 9, the configurations that are identical to FIG. 6 will be given the same reference signs, and the description thereof will be omitted. In the embodiment shown in FIG. 9, the first signal leads 51 curves upward, and the second signal leads 52 curved downward. One ends of the first signal leads 51 cover upper surfaces of the first signal patterns 91, and one ends of the second signal leads 52 cover lower surfaces of the second signal patterns 92. The first signal leads 51 are fixed to the first signal patterns 91 by solders (omitted from drawings), and the second signal leads 52 are fixed to the second signal patterns 92 by solders (omitted from drawings).

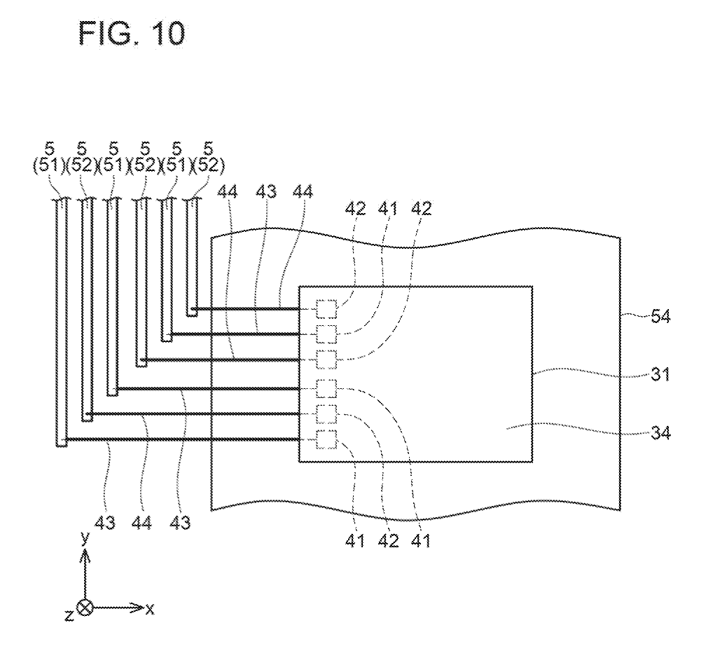

Further, the arrangement of the plurality of signal leads 5 (first signal leads 51 and second signal leads 52) is not limited to the above embodiments. For example, as shown in FIG. 10, the plurality of signal leads 5 may be arranged in a state with positions of their distal ends offset in a longitudinal direction. In FIG. 10, the configurations that are identical to FIG. 2 will be given the same reference signs, and the description thereof will be omitted. In the present embodiment, the positions of the distal ends are offset in three levels. The signal leads 5 that are farther away from the semiconductor chips 3 are made longer than the signal leads 5 that are closer to the semiconductor chips 3. The first signal leads 51 and the second signal leads 52 are arranged alternately. Further, a direction along which the plurality of signal leads 5 (first signal leads 51 and second signal leads 52) extend and a direction along which the wires (first wires 43 and second wires 44) extend intersect each other.

Further, in the above embodiments, IGBTs are used as the semiconductor chips 3, however, no limitation is made hereto, and MOSFETs or the like may be used as the semiconductor chips 3.

Specific examples of the present invention have been described in detail, however, these are mere exemplary indications and thus do not limit the scope of the claims. The art described in the claims includes modifications and variations of the specific examples presented above. Technical features described in the description and the drawings may technically be useful alone or in various combinations, and are not limited to the combinations as originally claimed. Further, the art described in the description and the drawings may concurrently achieve a plurality of aims, and technical significance thereof resides in achieving any one of such aims.

### REFERENCE SIGNS LIST

### 2: Semiconductor Module

### 3: Semiconductor Chip

### 4: Signal Electrode

### 5: Signal Lead

### 6: Sealing Resin

### 7: Insulator

### 9: Signal Pattern

### 22: Solder

### 23: Solder

### 24: Solder

### 31: First Semiconductor Chip

### 32: Second Semiconductor Chip

### 33: Front Surface

### 34: Rear Surface

### 35: Emitter Electrode

### 36: Collector Electrode

### 41: First Signal Electrode

### 42: Second Signal Electrode

### 43: First Wire

### 44: Second Wire

### 51: First Signal Lead

### 52: Second Signal Lead

### 53: Emitter Lead

### 54: Collector Lead (Heat Sink)

### 72: Insulator

### 91: First Signal Pattern

### 92: Second Signal Pattern

### 93: First Solder

### 94: Second Solder

### 143: First Wire

### 144: Second Wire

### 153: Emitter Pattern

1. A semiconductor module comprising:
a first semiconductor chip including a surface provided with a first signal electrode;
a second semiconductor chip arranged apart from the first semiconductor chip and including a surface on a first semiconductor chip side provided with a second signal electrode;
a first signal lead electrically connected to the first signal electrode; and
a second signal lead electrically connected to the second signal electrode,
wherein
the first signal lead and the second signal lead are arranged so that a height position of the first signal lead and a height position of the second signal lead match in a height direction that is toward the second semiconductor chip from the first semiconductor chip,
the surface of the first semiconductor chip provided with the first signal electrode and the surface of the second semiconductor chip provided with the second signal electrode face each other;
the first wire is connected to a surface of the first signal lead on a second semiconductor chip side, and is curved so as to protrude toward the second semiconductor chip side, and
the second wire is connected to a surface of the second signal lead on a first semiconductor chip side, and is curved so as to protrude toward the first semiconductor chip side.

2. (canceled)
